(19) United States
(12) Patent Application Publication
(10) Pub. No.: US 2008/0145958 A1
(43) Pub. Date: Jun. 19, 2008

(54) MONITORING OF ELECTROSTATIC DISCHARGE (ESD) EVENTS DURING SEMICONDUCTOR MANUFACTURE USING ESD SENSITIVE RESISTORS

(75) Inventors: Michel J. Abou-Khalil, Essex Junction, VT (US); Robert J. Gauthier, Hinesburg, VT (US); Tom C. Lee, Essex Junction, VT (US); Junjun Li, Williston, VT (US); Souvick Mitra, Burlington, VT (US); Christopher Stephen Putnam, Hinesburg, VT (US)

Correspondence Address: WOOD, HERRON & EVANS, LLP (IBM-BUR), 2700 CAREW TOWER, 441 VINE STREET, CINCINNATI, OH, 45202, US

(73) Assignee: INTERNATIONAL BUSINESS MACHINES CORPORATION, Armonk, NY (US)

(21) Appl. No.: 11/611,258

(22) Filed: Dec. 15, 2006

(51) Int. Cl. H01L 21/66; H01L 23/58

(52) U.S. Cl. 438/18; 257/48; 257/E21.531; 257/E23.002

(57) ABSTRACT

A monitor semiconductor chip that incorporates ESD sensitive resistors is subjected to the same steps in a semiconductor manufacturing process to which functional semiconductor chips are subjected. The ESD sensitive resistors are configured to experience non-volatile changes in resistance in response to ESD events, such that the resistors retain the changes in resistance after dissipation of the ESD events have occurred. As a result, the occurrence of an ESD event, and in some instances, the magnitude of an ESD event, can be detected by monitoring the resistance of the ESD sensitive resistors after one or more steps in a semiconductor manufacturing process.

### FIELD OF THE INVENTION

The invention is generally directed to semiconductor manufacture, and in particular to the effects of electrostatic discharge (ESD) on semiconductor chips during manufacture.

### BACKGROUND OF THE INVENTION

One of the principal cost factors associated with the manufacture of semiconductor integrated circuits, or chips, is the yield of the manufacturing process. Decreasing the number of defective chips that are manufactured, as well as detecting failures earlier in the manufacturing process to avoid further processing of defective chips, can have a substantial impact on the profitability of a manufacturing process.

A substantial source of defects in many semiconductor manufacturing processes is damage resulting from ESD events. An ESD event may cause extremely high currents to flow through the semiconductor devices in a chip, causing device junctions, gate oxides, and other adjacent structures to be permanently damaged. ESD events can occur at a number of stages during manufacture, including during various fabrication, testing, and packaging steps. ESD events may be caused, for example, by processing tools or even by the workers handling chips or the wafers upon which such chips are manufactured.

The occurrence of an ESD event that permanently damages a semiconductor chip during the manufacturing process is typically not addressed until the semiconductor chip has been found to fail final testing. Consequently, even if the ESD event occurs relatively early in the manufacturing process, the failed semiconductor chip will often continue through most or all of the subsequent manufacturing steps. Furthermore, by the time the semiconductor chip has been found to fail, it is often difficult, if not impossible, to determine when and where the ESD event occurred. In addition, ESD events are often not random and isolated occurrences, but instead are often recurring and caused by the same source, e.g., defective tooling or problematic handling processes.

Between fabrication, testing and packaging, a manufacturing process for semiconductor chips can involve hundreds of steps, with the chips handled and transported between numerous tools at many points in the process. Consequently, locating the source of ESD events in a manufacturing process can be extremely difficult. A significant need therefore exists in the art for an improved manner of diagnosing the source of ESD events within a semiconductor manufacturing process.

### SUMMARY OF THE INVENTION

The invention addresses these and other problems associated with the prior art by subjecting a monitor semiconductor chip that incorporates ESD sensitive resistors to the same steps in a semiconductor manufacturing process to which functional semiconductor chips are subjected. The ESD sensitive resistors are configured to experience non-volatile changes in resistance in response to ESD events, such that the resistors retain the changes in resistance after dissipation of the ESD events have occurred. As a result, the occurrence of an ESD event, and in some instances, the magnitude of an ESD event, can be detected by monitoring the resistance of the ESD sensitive resistors after one or more steps in a semiconductor manufacturing process.

In one embodiment of the invention, the monitor semiconductor chip may be configured with a pad layout that matches that of a functional semiconductor chip, and with ESD sensitive resistors disposed in circuit paths coupled to the pads of the chip. As such, the monitor semiconductor chip may be processed through semiconductor manufacturing steps in place of a functional semiconductor chip, and ESD events can be detected by monitoring for a change in resistance in any of the ESD sensitive resistors in the monitor semiconductor chip after completion of each of the semiconductor manufacturing steps.

These and other advantages and features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there is described exemplary embodiments of the invention.

### BRIEF DESCRIPTION OF THE DRAWINGS

FIG. 1 is a block diagram of a monitor semiconductor chip suitable for use in monitoring for ESD events during the manufacture of semiconductor chips in a manner consistent with the invention.

FIG. 2 is a graph of the resistance of several exemplary ESD sensitive resistors after being subjected to transmission line pulse (TLP) stressing.

FIG. 3 is a top plan view of an exemplary monitor wafer incorporating an array of monitor semiconductor chips configured in the manner illustrated in FIG. 1.

FIG. 4 is a top plan view of an exemplary functional wafer incorporating an array of functional semiconductor chips, with selected functional semiconductor chips replaced with monitor semiconductor chips configured in the manner illustrated in FIG. 1.

FIG. 5 is a flowchart illustrating a semiconductor manufacturing process incorporating ESD monitoring in a manner consistent with the invention, and using monitor semiconductor chips configured in the manner illustrated in FIG. 1.

FIGS. 6A-6D are graphs of the resistance of four exemplary circuit paths in a monitor semiconductor chip after five steps are performed in an exemplary semiconductor manufacturing process.

### DETAILED DESCRIPTION

The embodiments described hereinafter utilize a monitor semiconductor chip that incorporates a plurality of ESD sensitive resistors disposed in circuit paths coupled to the pads of the monitor semiconductor chip to detect ESD events to which the monitor semiconductor chip is exposed during a semiconductor manufacturing process. The ESD sensitive resistors experience non-volatile changes in resistance under ESD stress such that the resistors retain the changes in resistance after dissipation of an ESD event has occurred.

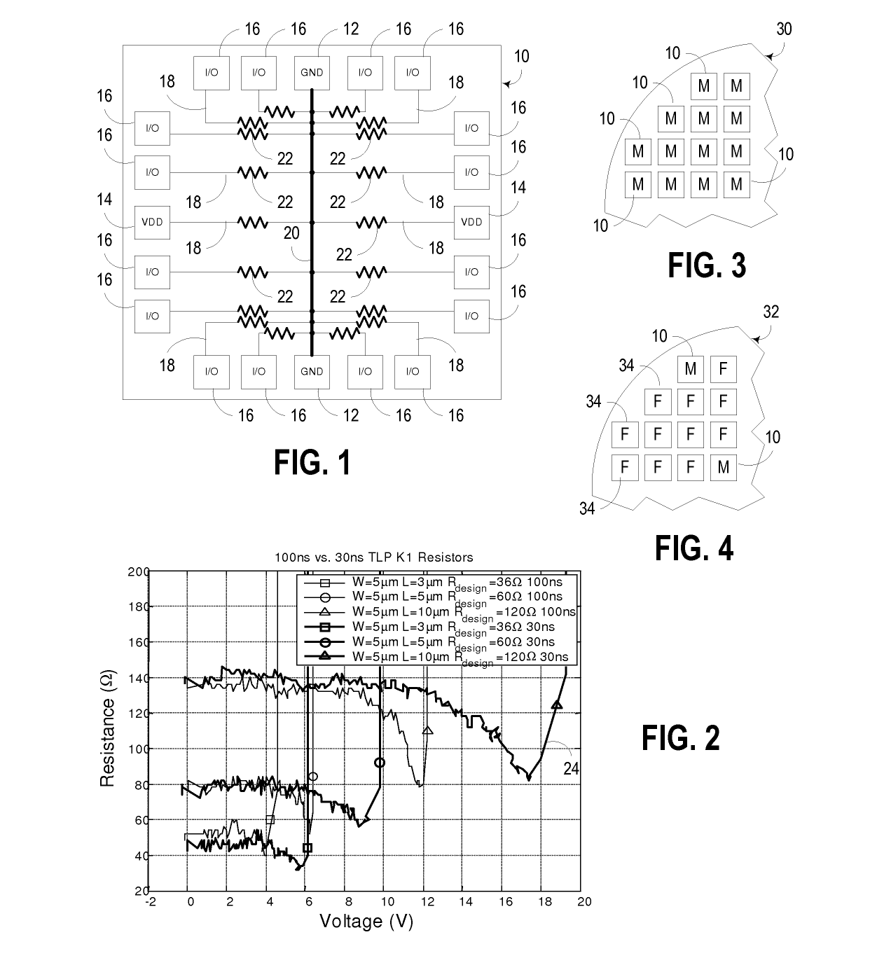

Turning to the Drawings, wherein like numbers denote like parts throughout the several views, FIG. 1 illustrates a monitor semiconductor chip 10 suitable for use in monitoring for ESD events during the manufacture of semiconductor chips in a manner consistent with the invention. Chip 10 includes a pad layout comprising a plurality of pads, including, for example, ground pads 12, power (VDD) pads 14 and I/O pads 16. The chip desirably has a pad layout that matches that of a functional semiconductor chip that the monitor semiconductor chip replaces, such that any steps in the manufacturing process that interact with the pads on the functional chips can interact in the same manner with the monitor chips. The pad layout may or may not be identical to that of the functional chip; however, given the desire to detect ESD events that affect functional chips, it is desirable for the monitor chip to be capable of undergoing the same operations and handling as the functional chips and any functional wafers upon which such chips are disposed.

Chip 10 includes a plurality of circuit paths 18 extending between the pads 12, 14, 16 of the chip. It maybe desirable, for example, to utilize a ground bus 20 coupled to the ground pads 12, with circuit paths 18 connecting each of the power 14 and I/O pads 16 to the ground bus 20. In the alternative, no ground bus may be used.

Within each circuit path 18 is disposed an ESD sensitive resistor 22. In the illustrated embodiment, a resistor 22 is disposed between ground bus 20 and each power and I/O pad 14, 16. By doing so, a circuit path crossing a resistor is defined between ground pads 12 and each power and I/O pad 14, 16. Furthermore, circuit paths may be defined between pairs of power and I/O pads 14, 16 given that all such pads are coupled to the ground bus, whereby a pair of resistors 22 are defined along such paths. In the alternative, dedicated ESD sensitive resistors may be provided between each pair of pads between which a circuit path is desired.

Also, in the illustrated embodiment, a monitor chip 10 includes no passive or active circuit components disposed in the circuit paths other than ESD sensitive resistors. In some embodiments, however, active and/or passive components may be disposed on a monitor chip, either within or outside of the circuit paths within which the ESD sensitive resistors are disposed. For example, capacitors and/or non-ESD sensitive resistors may be added to the circuit paths to appropriately scale or manipulate the ESD level to which the ESD sensitive resistors are exposed.

Each ESD sensitive resistor is of a type that is capable of experiencing a non-volatile change in resistance when under ESD stress such that the resistor retains the change in resistance after dissipation of an ESD event has occurred. In the illustrated embodiment, for example, each resistor may be implemented as a tantalum nitride (TaN) thin film resistor (also referred to herein as a K1 resistor) similar in design to thin film structures that are conventionally used for programmable fuses. One suitable design for such a structure is disclosed, for example, in U.S. Patent Publication No. 2006/0163,685, which is incorporated by reference herein. As is known in the art, a TaN thin film structure, when subjected to a high current, experiences self-heating and electromigration effects that disrupt the continuity of the structure. Such structures are conventionally used as programmable fuses, with a high current intentionally (and non-transiently) induced over such a structure whenever it is desired to “blow” the fuse and create an open circuit.

It has been found, however, that such structures also have the property of decreasing in resistance prior to “blowing” (i.e., forming an open circuit). As such, when properly sized and configured, such structures may also be used as variable resistors that decrease in resistance in response to the ranges of voltages and currents that are typically associated with transient ESD events. Moreover, these changes in resistance are non-volatile in nature, and are retained even after ESD events have dissipated. Consequently, in many instances the magnitude of an ESD event can be determined from the change in resistance experienced by an ESD sensitive resistor.

As an example, FIG. 2 illustrates a graph of the resistance of several exemplary TaN ESD sensitive resistors after being subjected to transmission line pulse (TLP) stressing. The lighter weighted lines illustrate TLP stressing of 36, 60 and 120 Ω resistors at different voltages with a 100 ns pulse width, with the stronger weighted lines illustrating TLP stressing of 36, 60 and 120 Ω resistors using a 30 ns pulse width. The 36 Ω resistors have dimensions of 5 μm (w)×3 μm (l), the 60 Ω resistors have dimensions of 5 μm (w)×5 [m (l), and the 120 Ω resistors have dimensions of 5 μm (w)×10 μm (l). All resistors have a thickness of about 40 nm.

As shown, for example, by plot 24 for a 120 Ω resistor subjected to 30 ns pulse widths, above a TLP voltage of around 10 volts, the resistor exhibits a negative temperature coefficient of resistance (TCR), with the resistance decreasing as the voltage increases, until the resistor ultimately becomes inoperable (open) about 17-18 volts. It can also be seen that the pulse width of the TLP pulses also has a direct effect on the self-heating behavior of the resistors by comparing this graph with that for the same resistor with 100 ns pulse widths. It has been found that the changes in resistance are permanent above a certain ESD TLP stress level, and that the resistance shift is dependent on both pulse width and stress level. As such, by properly configuring the dimensions of the resistors to accommodate anticipated ESD stresses that fall within the range at which the resistors experience the non-volatile changes in resistance, which would be well within the abilities of one of ordinary skill in the art having the benefit of the instant disclosure, the resistors may be used to detect ESD events.

In addition, due to the repeatable nature of the resistance changes for such resistors, it will be appreciated that in many instances the magnitude of ESD events, e.g., based upon an electrical characteristic such as the ESD voltage and/or the pulse width, may be ascertained from the changes in resistance. In addition, when a resistor is subjected to multiple ESD events, the maximum ESD event among those events will typically be represented by the final resistance value.

While a TaN structure is used in the illustrated embodiment, it will be appreciated that other structures incorporating similar characteristics, such as self-heating and/or electromigration when subjected to current, may be used in the alternative. For example, other thin film structures, e.g., other thin film structures formed of TaN may be used in the alternative, as may other structures formed of polysilicon, silicide, or similar materials.

In operation, a monitor semiconductor chip 10 may be fabricated in an array on a dedicated monitor wafer, e.g., as illustrated by monitor wafer 30 of FIG. 3. In the alternative, a monitor semiconductor chip 10 may be fabricated alongside functional semiconductor chips on a functional wafer, e.g. as illustrated by functional wafer 32 of FIG. 4, which incorporates both monitor chips 10 as well as functional chips 34.

When fabricated alongside functional chips, monitor chips are typically fabricated concurrently with the functional chips using the same basic fabrication steps, as will be apparent to one of ordinary skill in the art. Typically, the monitor chips are disposed within the same array as the functional chips, with the monitor chips replacing functional chips at one or more locations in the array, so that tools can access the monitor chips in essentially the same manner as the functional chips, and so that the monitor chips are exposed to similar conditions as the functional chips during processing. On the other hand, when fabricated on dedicated monitor wafers, the monitor wafers are typically processed along with one or more functional wafers in a batch process, such that the monitor wafers are exposed to similar conditions as the functional wafers.

It will also be appreciated that at stages of a manufacturing process that occur subsequent to chips or dice being separated from the wafers (e.g., during packaging), the monitor and functional chips may still be processed in a batch process, but with the monitor and functional chips no longer disposed on the same or different wafers. In such instances, whether a monitor chip is fabricated on the same or different wafer from a functional chip is immaterial.

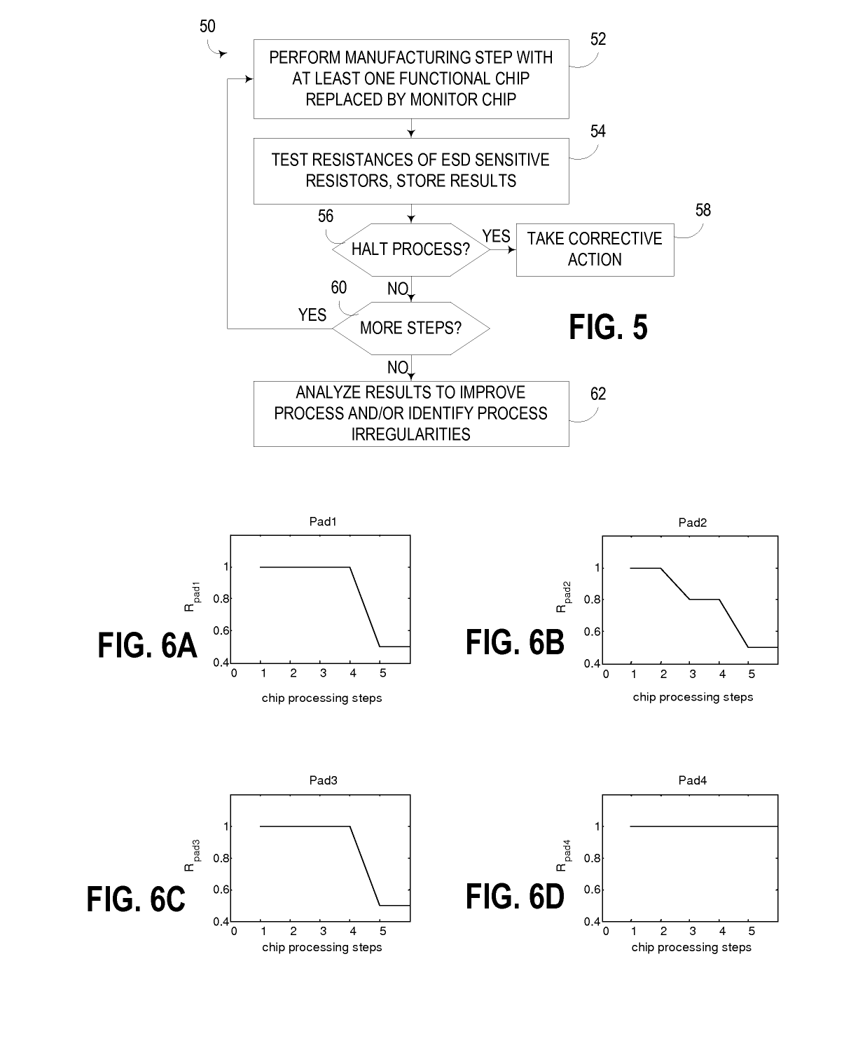

FIG. 5 illustrates a flowchart of a semiconductor manufacturing process 50 incorporating ESD monitoring in a manner consistent with the invention, and using the monitor semiconductor chips 10 described above. Process 50 begins in block 52 by performing a manufacturing step on one or more functional chips with one or more functional chips replaced by a monitor chip. As noted above, in the case of a manufacturing step that is performed on wafers, such a batch process may involve performing a step on a functional wafer that includes a monitor chip incorporated in place of a functional chip, or alternatively, on a monitor wafer that is processed as a batch with one or more functional wafers. The manufacturing step may include practically any type of semiconductor manufacturing related step, including various types of fabrication steps, testing steps and/or packaging steps.

Next, in block 54 the resistance of each ESD sensitive resistor in one or more monitor chips are tested and stored. Such testing may occur as a discrete step, or may be performed in connection with other testing performed on the functional chips during the manufacturing process, e.g., in connection with in-line testing, BEOL testing, M1 testing, M2 testing, wafer final testing, module testing, board testing, packaging testing, etc. If done in connection with other testing, typically the resistance of the ESD sensitive resistors can be tested using conventional testing tools.

Next, block 56 determines whether, as a result of testing, processing should be halted for the associated batch of chips. For example, if a high magnitude ESD event is detected, it may be desirable to discontinue further processing of the batch and avoid the time and expense of subjecting potentially defective chips to further manufacturing steps. As such, as shown in block 58, corrective action may be taken, e.g., to discard a batch of chips, to examine handling procedures and to ensure a more tightly controlled ESD environment for the future handling of the chips, etc.

Otherwise, if processing does not need to be halted, in block 58 it is determined whether more steps remain in the manufacturing process. If so, additional steps are performed as described above in connection with block 54. Otherwise, as shown in block 62, the results of the ESD monitoring may be analyzed and used to improve the manufacturing processor and/or identify any process irregularities, e.g., faulty equipment, faulty handling processes, environments that are otherwise improperly controlled for ESD, etc.

It will be appreciated that testing of the ESD sensitive resistors may occur only after certain steps in a manufacturing process. While more frequent testing may assist in the ability to isolate ESD events to specific steps in a manufacturing process, in many instances it will not be necessary to perform such testing after every step.

As a further illustration of ESD monitoring in the manner described herein, FIGS. 6A-6D illustrate the resistance of four exemplary circuit paths (coupled respectively to pads 1-4) in a monitor semiconductor chip after five steps (1-5) are performed in an exemplary semiconductor manufacturing process. As can be seen from FIG. 6B, pad 2 experienced a moderate level of ESD stress in step 3 of the process. Then, as seen from FIGS. 6A, 6B and 6C, pads 1-3 experienced a more severe level of ESD stress in step 5 of the process. Consequently, by monitoring the resistance of each of the ESD sensitive resistors coupled to pads 1-4, both the magnitude and the step associated with each ESD event can be ascertained and used to isolate and identify the potential sources of such events.

It will be appreciated that ESD event monitoring as described herein may be used to monitor for a number of different types of ESD-related events. For example, ESD event monitoring may be used to detect events based upon the Human Body Model (HBM), the Machine Model (MM) and the Charged Device Model (CDM), each of which is well known in the art.

It will be also appreciated that ESD event monitoring as described herein may be used in a number of applications to improve semiconductor manufacturing processes. For example, for chips/products that suffer ESD problems because of either poor ESD protection design or severe ESD environment, embodiments of the invention are capable of identifying when and where ESD events happen. For chips/products that do not have ESD problems (possibly because of good ESD protection design), statistical ESD events analysis (monitoring of non-critical ESD stresses) may still be performed for identifying possible ESD protection area reductions. Also, for new manufacturing line ESD reliability qualification, embodiments of the invention often enable earlier readout of ESD excursions. Other benefits of ESD monitoring as described herein will be apparent to one of ordinary skill in the art having the benefit of the instant disclosure.

Various additional modifications may be made to the illustrated embodiments without departing from the spirit and scope of the invention. Therefore, the invention lies in the claims hereinafter appended.

What is claimed is:

1. A method of monitoring for electrostatic discharge (ESD) events in a semiconductor manufacturing process, the method comprising:
for a manufacturing process capable of being performed on a functional semiconductor chip that includes a first plurality of pads disposed in a predetermined pad layout, incorporating a monitor semiconductor chip in place of the functional semiconductor chip, wherein the monitor semiconductor chip includes:
a second plurality of pads disposed in the predetermined pad layout;
a plurality of circuit paths coupled to the second plurality of pads; and
a plurality of ESD sensitive resistors, each disposed in a circuit path among the plurality of circuit paths and configured to experience a non-volatile change in resistance in response to an ESD event;
performing a plurality of semiconductor manufacturing steps in the manufacturing process with the monitor semiconductor chip incorporated in place of the functional semiconductor chip; and
monitoring for an ESD event occurring during any of the plurality of semiconductor manufacturing steps by monitoring for a change in resistance in at least one of the plurality of ESD sensitive resistors in the monitor semiconductor chip after completion of each of the plurality of semiconductor manufacturing steps.

2. The method of claim 1, wherein each of the ESD resistors comprises a tantalum nitride resistor that is configured to retain a change in resistance occurring in response to an ESD event after dissipation of the ESD event has occurred.

3. The method of claim 1, further comprising, in response to detecting an ESD event as a result of detecting a change in resistance in a first ESD sensitive resistor among the plurality of ESD sensitive resistors, determining an electrical characteristic of the ESD event selected from the group consisting of an ESD voltage and a pulse width associated with the ESD event.

4. The method of claim 1, wherein the monitor semiconductor chip is disposed on a wafer comprising a plurality of functional semiconductor chips such that the monitor semiconductor chip is exposed to similar conditions as the functional semiconductor chips on the wafer.

5. The method of claim 1, wherein the monitor semiconductor chip is disposed on a monitor wafer comprising a plurality of monitor semiconductor chips arranged in an array, and wherein performing the plurality of semiconductor manufacturing steps includes performing each semiconductor manufacturing step on the monitor wafer in a batch process with a plurality of functional wafers that include arrays of functional semiconductor chips such that the monitor semiconductor chips on the monitor wafer are exposed to similar conditions as the functional semiconductor chips on the functional wafers.

6. A monitor semiconductor chip for monitoring electrostatic discharge (ESD) events in a semiconductor manufacturing process capable of being performed on a functional semiconductor chip, the monitor semiconductor chip comprising:
a plurality of pads disposed in a predetermined pad layout associated with the functional semiconductor chip;
a plurality of circuit paths coupled to the plurality of pads; and
a plurality of ESD sensitive resistors, each disposed in a circuit path among the plurality of circuit paths and configured to experience a non-volatile change in resistance in response to an ESD event occurring in the circuit path within which such ESD sensitive resistor is disposed such that such ESD sensitive resistor retains the change in resistance after dissipation of the ESD event has occurred.

7. The monitor semiconductor chip of claim 6, wherein the plurality of pads includes a plurality of power pads, a plurality of input/output pads, and at least one ground pad, and wherein at least a first subset of the plurality of ESD sensitive resistors are coupled between the plurality of power pads and the at least one ground pad, and at least a second subset of the plurality of ESD sensitive resistors are coupled between the plurality of input/output pads and the at least one ground pad.

8. The monitor semiconductor chip of claim 6, wherein the monitor semiconductor chip includes no passive or active circuit components disposed in the circuit paths other than the plurality of ESD sensitive resistors.

9. The monitor semiconductor chip of claim 6, wherein each of the ESD sensitive resistors comprises a tantalum nitride resistor.
